(19) United States
(12) Patent Application Publication
(10) Pub. No.: US 2026/0112860 A1
(43) Pub. Date: Apr. 23, 2026

(54) LASER BAR CHIP AND METHOD OF MANUFACTURING A LASER BAR CHIP

(71) Applicant: ams-OSRAM International GmbH, Regensburg (DE)

(72) Inventors: Nicole BERNER, Walderbach (DE); Andreas FROEHLICH, Regensburg (DE); Erik HEINEMANN, Regensburg (DE); Jan MARFELD, Regensburg (DE); Tobias HAUPELTSHOFER, Breitenbrunn (DE); Joerg Erich SORG, Regensburg (DE)

(21) Appl. No.: 19/138,793

(22) PCT Filed: Dec. 14, 2023
(86) PCT No.: PCT/EP2023/085842

§ 371 Date: Jun. 13, 2025

(30) Foreign Application Priority Data
Dec. 16, 2022 (DE) 10 2022 133 588.7

(51) Int. Cl. H01S 5/042; H01S 5/40

(52) U.S. Cl. CPC H01S 5/04256; H01S 5/4025

(57) ABSTRACT

A laser bar chip includes at least a first laser diode, a second laser diode and a third laser diode. The first laser diode, the second laser diode and the third laser diode each include a waveguide structure. The laser bar chip includes a first cathode contact which is electrically connected to the first laser diode, and a second cathode contact which is electrically connected to the second laser diode and the third laser diode. The laser bar chip also includes a first anode contact which is electrically connected to the first laser diode and to the second laser diode.

The present invention relates to a laser bar chip and to a method of manufacturing a laser bar chip.

Laser bar chips comprising a plurality of laser diodes are known in the prior art. In known laser bar chips, the laser diodes have a common cathode.

It is an object of the present invention to provide a laser bar chip. It is a further object of the present invention to specify a method of manufacturing a laser bar chip. These objects are achieved by a laser bar chip and by a method of manufacturing a laser bar chip comprising the features of the independent claims. Various refinements are specified in the dependent claims.

A laser bar chip comprises at least a first laser diode and a second laser diode. The first laser diode and the second laser diode each comprise a waveguide structure. The laser bar chip comprises a first cathode contact which is electrically connected to the first laser diode, and a second cathode contact which is electrically connected to the second laser diode.

In this laser bar chip, the first laser diode and the second laser diode can be driven independently of one another via the first cathode contact and the second cathode contact. The driving via the cathode contacts in this case makes it possible to use n-channel FETs for switching the current flow through the laser diodes. This can advantageously make very fast switching possible. A smaller design can also be realized, since n-channel FETs can be designed to be smaller than comparable p-channel FETs.

In one embodiment of the laser bar chip, the latter comprises a third laser diode. In this case, the second cathode contact is electrically connected to the third laser diode. This advantageously makes it possible to design the laser bar chip with a number of laser diodes which is greater than the number of cathode contacts. As a result, the laser bar chip can advantageously also be designed with a large number of laser diodes while maintaining a required minimum size of the cathode contacts.

In one embodiment of the laser bar chip, the latter comprises a first anode contact which is electrically connected to the first laser diode. This makes it possible to supply the first laser diode with electrical voltage and electrical current via the first anode contact and the first cathode contact.

In one embodiment of the laser bar chip, the first anode contact is electrically connected to the second laser diode. Advantageously, as a result, only one anode contact is required for supplying the first laser diode and the second laser diode, which makes it possible to design the laser bar chip with compact dimensions even while maintaining a minimum size of the first anode contact. In this case, the first cathode contact and the second cathode contact make it possible to drive the first laser diode and the second laser diode individually despite the first anode contact being used jointly by the first laser diode and the second laser diode.

In one embodiment of the laser bar chip, the latter comprises a second anode contact which is electrically connected to the third laser diode. This makes it possible to drive the second laser diode and the third laser diode independently of one another even when the second cathode contact is electrically connected to the second laser diode and the third laser diode.

In one embodiment of the laser bar chip, an electrically non-conductive passivation is arranged on the waveguide structure of the first laser diode. In the region of the first anode contact, the passivation is opened, so that the first anode contact is electrically connected to the first laser diode. The second anode contact is electrically insulated from the first laser diode by the passivation. This advantageously makes it possible to arrange the first anode contact and the second anode contact with a flexibly predefinable geometry on a surface of the laser bar chip and in this case nevertheless to ensure individual contacting of individual laser diodes by individual anode contacts.

In one embodiment of the laser bar chip, the first anode contact is arranged on a first surface of the laser bar chip. The first cathode contact and the second cathode contact are arranged on a second surface of the laser bar chip. This advantageously makes it possible to utilize the space available on the first surface and the space available on the second surface of the laser bar chip, so that the laser bar chip can be designed with a minimum overall size while maximizing the size of the anode contacts and the cathode contacts.

In one embodiment of the laser bar chip, a rewiring structure is formed on the second surface of the laser bar chip. This rewiring structure can make an even more flexible design of the geometry of the cathode contacts possible. In addition, the rewiring structure can make rewiring and combining of individual cathode contacts possible.

In one embodiment of the laser bar chip, the first anode contact, the first cathode contact and the second cathode contact are arranged together on a first surface of the laser bar chip. This advantageously makes complete electrical contacting of the laser bar chip via the first surface possible.

In one embodiment of the laser bar chip, a rewiring structure is formed on the first surface of the laser bar chip. This rewiring structure can make an even more flexible geometry of the electrical contact areas arranged on the first surface possible. The rewiring structure can also make rewiring and electrical combining of individual electrical contact areas possible.

In one embodiment of the laser bar chip, an epitaxial layer of the laser bar chip comprises an electrically non-conductive interruption between the first laser diode and the second laser diode. This makes it possible to achieve cathode-side decoupling of the first laser diode and the second laser diode.

In one embodiment of the laser bar chip, the epitaxial layer is arranged on an electrically conductive substrate. In this case, a first section of the substrate and a second section of the substrate are electrically insulated from one another by an electrically non-conductive region. The first cathode contact is electrically connected to the first laser diode via the first section of the substrate. The second cathode contact is electrically connected to the second laser diode via the second section of the substrate. The subdivision of the substrate into the first section and the second section makes cathode-side decoupling of the first laser diode and the second laser diode possible and individual cathode-side contacting of the first laser diode and the second laser diode possible.

In another embodiment of the laser bar chip, the epitaxial layer is arranged on an electrically non-conductive substrate. In this case, the substrate comprises an electrically conductive first through-contact and an electrically conductive second through-contact. The first cathode contact is electrically connected to the first laser diode via the first through-contact. The second cathode contact is electrically connected to the second laser diode via the second through-contact. The first through-contact and the second through-contact thereby make individual cathode-side contacting of the first laser diode and the second laser diode of the laser bar chip possible.

A method of manufacturing a laser bar chip comprises steps for providing a substrate comprising an epitaxial layer arranged on a top side, for forming at least a first laser diode and a second laser diode in the epitaxial layer, wherein the first laser diode and the second laser diode each comprise a waveguide structure, and for forming a first cathode contact which is electrically connected to the first laser diode, and a second cathode contact which is electrically connected to the second laser diode.

This method advantageously makes it possible to manufacture a laser bar chip comprising at least two laser diodes which are driven independently of one another via individual cathode contacts. In this case, n-channel FETs can advantageously be used for driving, which can make fast driving possible.

In one embodiment of the method, the latter comprises a further step for generating an electrically non-conductive interruption in the epitaxial layer between the first laser diode and the second laser diode. This advantageously achieves cathode-side decoupling of the first laser diode and the second laser diode.

In one embodiment of the method, the substrate is electrically non-conductive. In this case, the method comprises a further step for applying an electrically conductive first through-contact and an electrically conductive second through-contact in the substrate. The first cathode contact is electrically connected to the first laser diode via the first through-contact. The second cathode contact is electrically connected to the second laser diode via the second through-contact. The through-contacts applied in this way therefore make individual cathode-side contacting of the first laser diode and the second laser diode possible.

In one embodiment of the method, the substrate is electrically conductive. In this case, the method comprises a further step of applying an electrically non-conductive region in the substrate in order to electrically insulate a first section of the substrate and a second section of the substrate from one another. The first cathode contact is electrically connected to the first laser diode via the first section of the substrate. The second cathode contact is electrically connected to the second laser diode via the second section of the substrate. In this variant of the method, the subdivision of the substrate into the first section and the second section makes individual cathode-side contacting of the first laser diode and the second laser diode possible.

In one embodiment of the method, the electrically non-conductive interruption in the epitaxial layer and the electrically non-conductive region in the substrate are generated jointly by a FIB process (irradiation with a focused ion beam). This advantageously makes precise formation of the electrically non-conductive interruption in the epitaxial layer and of the electrically non-conductive region in the substrate possible.

In one embodiment of the method, the electrically non-conductive interruption is generated by etching a trench in the epitaxial layer. This method advantageously makes reliable and precise formation of the electrically non-conductive interruption in the epitaxial layer possible.

In one embodiment of the method, the trench is filled with an electrically non-conductive material. This advantageously enables subsequent covering of the trench filled with the electrically non-conductive material by further material.

The above-described properties, features and advantages of this invention, and the way in which they are achieved, will become clearer and more clearly understood in conjunction with the following description of the example embodiments, which are explained in more detail in conjunction with the drawings. In the figures, in each case in schematic representation,

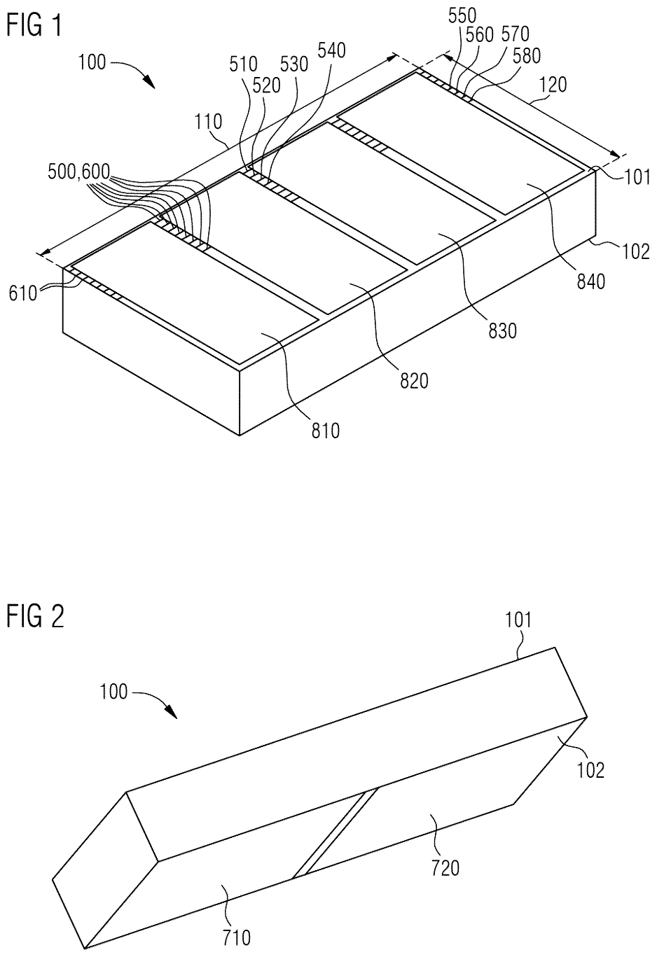

FIG. 1 shows a view of a first surface of a laser bar chip comprising a plurality of anode contacts;

FIG. 2 shows a view of a second surface of the laser bar chip comprising a plurality of cathode contacts;

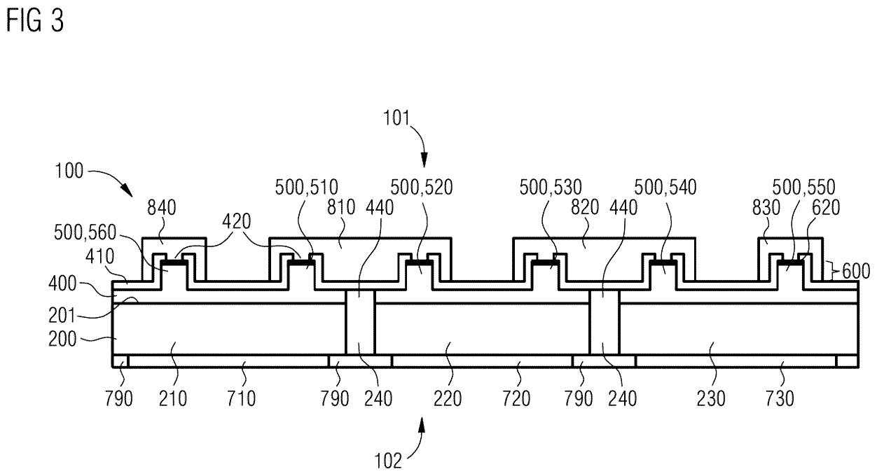

FIG. 3 shows a sectional side view of a variant of a laser bar chip;

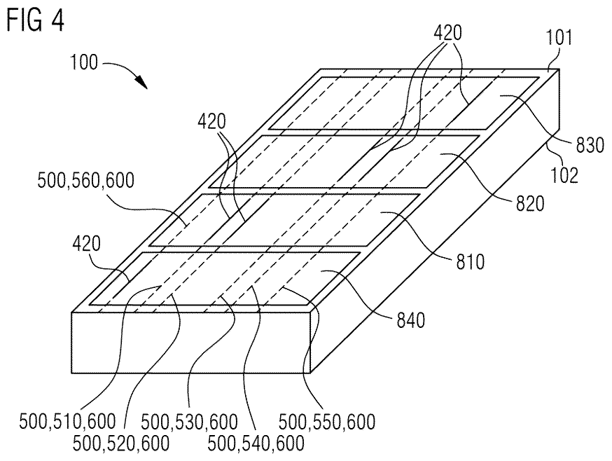

FIG. 4 shows a partially transparent perspective view of this variant of the laser bar chip;

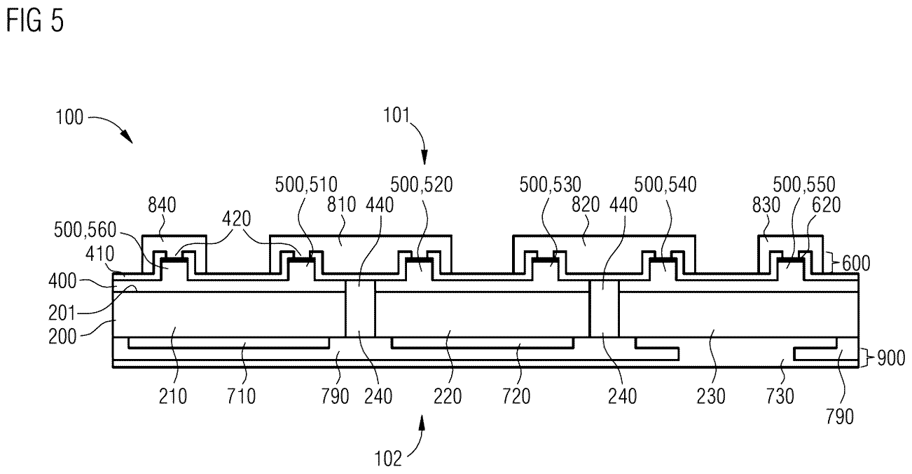

FIG. 5 shows a sectional side view of a further variant of a laser bar chip;

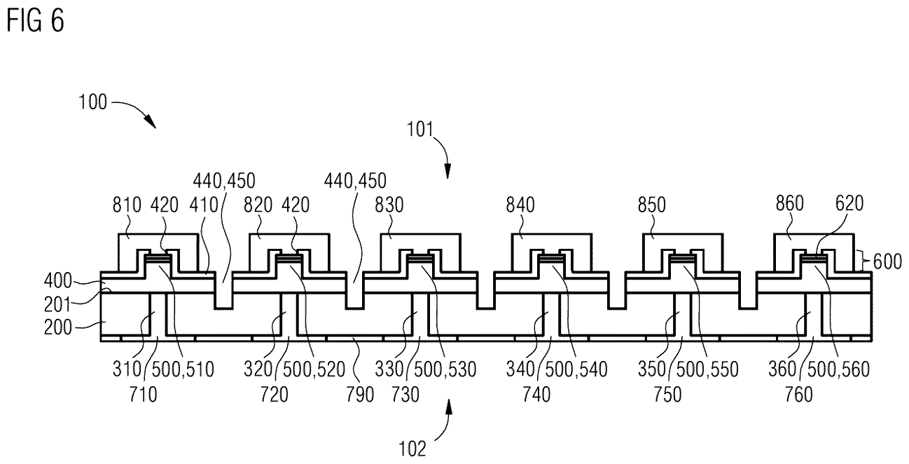

FIG. 6 shows a sectional side view of a further variant of a laser bar chip;

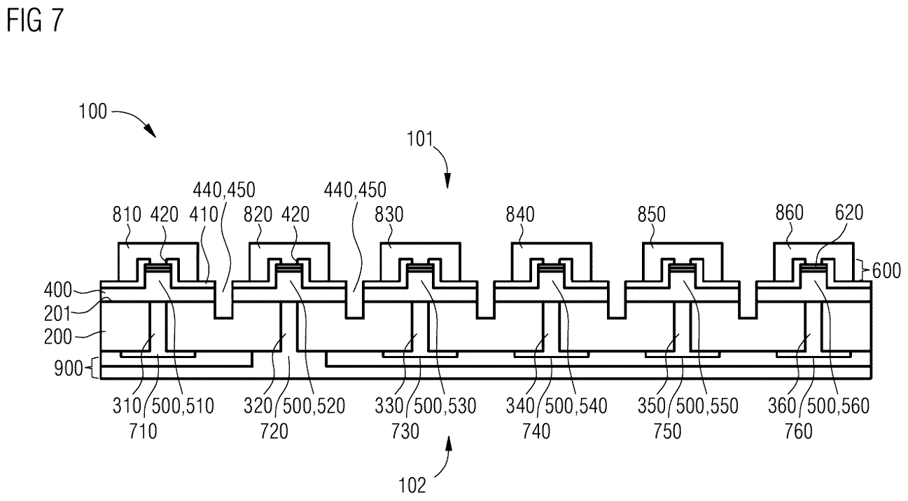

FIG. 7 shows a sectional side view of a further variant of a laser bar chip;

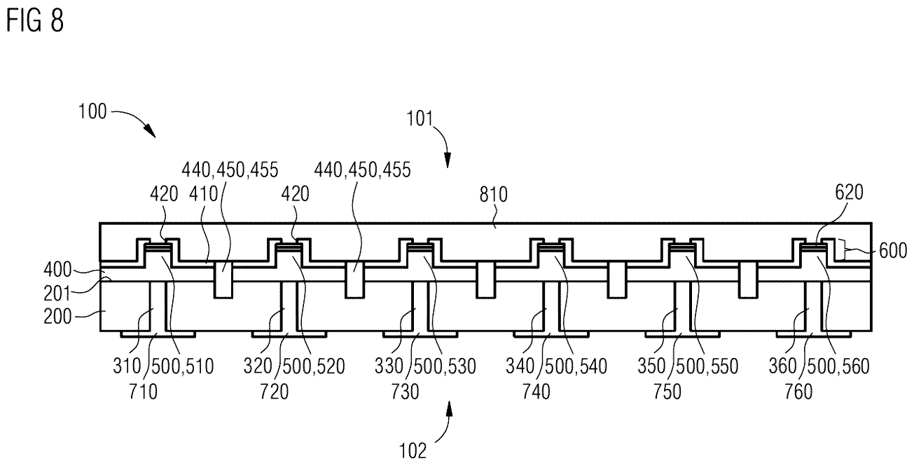

FIG. 8 shows a sectional side view of a further variant of a laser bar chip;

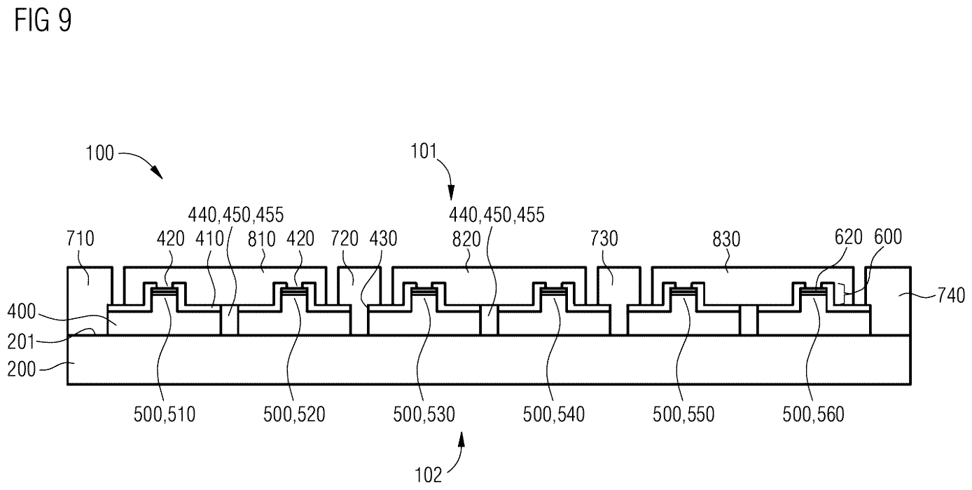

FIG. 9 shows a sectional side view of a further variant of a laser bar chip; and

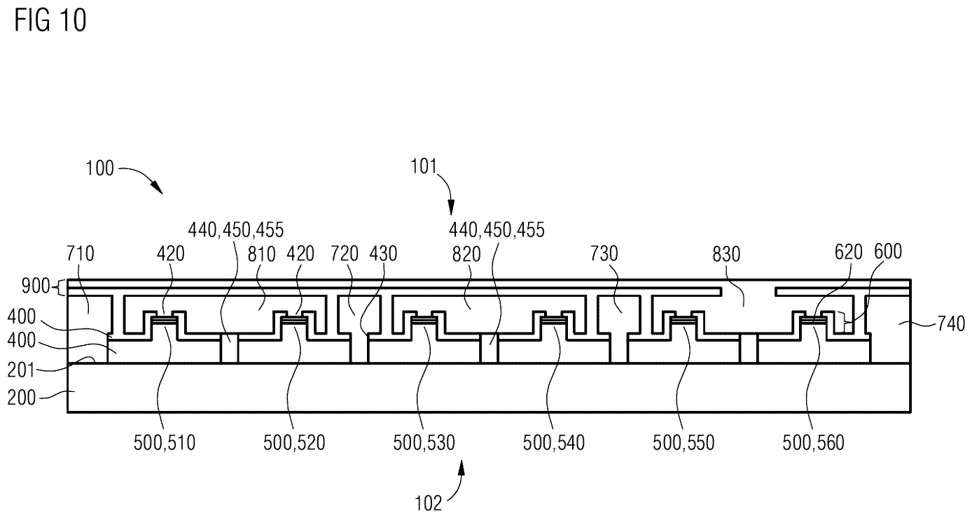

FIG. 10 shows a sectional side view of a further variant of a laser bar chip.

FIG. 1 shows a schematic perspective view of a first surface 101 of a laser bar chip 100. FIG. 2 shows a schematic perspective view of a second surface 102 of the laser bar chip 100 opposite the first surface 101.

The laser bar chip 100 has a cuboid basic shape with a length 110 and a width 120. The length 110 can be, for example, 600 μm and can be predefined, for example, by a minimum length of waveguide structures of laser diodes of the laser bar chip 100. The width 120 of the laser bar chip 100 can be, for example, 125 μm.

The laser bar chip 100 comprises a plurality of integrated laser diodes 500. In the example shown in FIGS. 1 and 2, the laser bar chip 100 comprises a first laser diode 500, 510, a second laser diode 500, 520, a third laser diode 500, 530, a fourth laser diode 500, 540, a fifth laser diode 500, 550, a sixth laser diode 500, 560, a seventh laser diode 500, 570 and an eighth laser diode 500, 580, which are arranged next to one another in this order. However, the laser bar chip 100 can also be designed with a different number of laser diodes 500.

Each of the laser diodes 500 comprises a waveguide structure 600, which can also be referred to as a ridge. Therefore, the laser bar chip 100 can also be referred to as a multi-ridge laser chip. In the example shown, the waveguide structures 600 of the laser diodes 500 are oriented parallel to one another and parallel to the edges of the laser bar chip 100 having the length 110 and are arranged on the first surface 101 of the laser bar chip 100. However, this is not absolutely necessary. In the example shown, the waveguide structures 600 of the laser diodes 500 are not distributed over the entire width 120 of the laser bar chip 100, but rather are arranged closer to one side of the laser bar chip 100. However, this can also be designed differently. At one longitudinal end of the waveguide structures 600, the laser diodes 500 each comprise an outcoupling facet 610, at which a laser beam emerges during operation of the respective laser diode 500.

A first anode contact 810, a second anode contact 820, a third anode contact 830 and a fourth anode contact 840 are arranged on the first surface 101 of the laser bar chip 100. In other variants of the laser bar chip 100, fewer or more than four anode contacts 810, 820, 830, 840 can be provided. The anode contacts 810, 820, 830, 840 are provided for electrical contacting of the laser bar chip 100, for example for contacting by bonding or soldering. The anode contacts 810, 820, 830, 840 comprise a metal suitable for electrical contacting, for example gold. It is expedient if the anode contacts 810, 820, 830, 840 are each of approximately the same size and together utilize the space available on the first surface 101 of the laser bar chip 100 as completely as possible. For example, each of the anode contacts 810, 820, 830, 840 can have a size of 134 μm by 105 μm.

A first cathode contact 710 and a second cathode contact 720 are arranged on the second surface 102 of the laser bar chip 100. In other variants of the laser bar chip 100, fewer or more than two cathode contacts 710, 720 can be provided. The cathode contacts 710, 720 are also provided for electrical contacting of the laser bar chip 100 and comprise a metal suitable for electrical contacting, for example gold. It is expedient if the cathode contacts 710, 720 have approximately the same size and together utilize the space available on the second surface 102 as completely as possible.

The anode contacts 810, 820, 830, 840 are provided for anode-side contacting of the laser diodes 500. The cathode contacts 710, 720 are provided for cathode-side electrical contacting of the laser diodes 500. It is expedient if each laser diode 500 can be individually addressed by a combination of a cathode contact 710, 720 and an anode contact 810, 820, 830, 840. For this purpose, for example, the first cathode contact 710 can be electrically connected to the first laser diode 500, 510, the third laser diode 500, 530, the fifth laser diode 500, 550 and the seventh laser diode 500, 570. The second cathode contact 720 is then electrically connected to the second laser diode 500, 520, the fourth laser diode 500, 540, the sixth laser diode 500, 560 and the eighth laser diode 500, 580. In this case, the first anode contact 810 can be connected to the first laser diode 500, 510 and the second laser diode 500, 520, while the second anode contact 820 is connected to the third laser diode 500, 530 and the fourth laser diode 500, 540, the third anode contact 830 is connected to the fifth laser diode 500, 550 and the sixth laser diode 500, 560 and the fourth anode contact 840 is connected to the seventh laser diode 500, 570 and the eighth laser diode 500, 580. Of course, other interconnections are also possible.

The anode contacts 810, 820, 830, 840 can be driven, for example, via p-channel FETs. The cathode contacts 710, 720 can be driven, for example, via n-channel FETs.

Various variants of the laser bar chip 100 are described below. In this case, the description is restricted in part to those aspects in which the respective variant of the laser bar chip 100 differs from the above-described variants of the laser bar chip 100. Otherwise, the preceding explanations also apply in each case to the further variants of the laser bar chip 100.

FIG. 3 shows a schematic sectional side view of a variant of the laser bar chip 100. In the variant shown in FIG. 3, the laser bar chip 100 comprises only the first laser diode 500, 510, the second laser diode 500, 520, the third laser diode 500, 530, the fourth laser diode 500, 540, the fifth laser diode 500, 550 and the sixth laser diode 500, 560. In this case, the first laser diode 500, 510, the second laser diode 500, 520, the third laser diode 500, 530, the fourth laser diode 500, 540 and the fifth laser diode 500, 550 are arranged next to one another in this order, while the sixth laser diode 500, 560 is arranged on the side of the first laser diode 500, 510 opposite the second laser diode 500, 520. In addition, the laser bar chip 100 also has a third cathode contact 730 in addition to the first cathode contact 710 and the second cathode contact 720.

The laser bar chip 100 comprises an electrically conductive substrate 200. The substrate 200 can be formed, for example, by a semiconductor material with an electrically conductive n-type doping. An epitaxial layer 400 is arranged on a top side 201 of the substrate 200. The waveguide structures 600 have been formed in the epitaxial layer 400 by partial removal of the epitaxial layer 400. In the region 240 of each waveguide structure 600, the epitaxial layer 400 comprises an active layer 620. In each laser diode 500, a part of the epitaxial layer 400 facing the substrate 200 forms an n-side cathode on one side of the active layer 620 and a part of the epitaxial layer 400 facing away from the substrate 200 forms a p-side anode on the other side of the active layer 620.

On the first surface 101 of the laser bar chip 100, the epitaxial layer 400 and the waveguide structures 600 formed therein are covered by an electrically non-conductive passivation 410. In the region of the waveguide structures 600 of the laser diodes 500, the passivation 410 comprises, at least in sections, anode openings 420 which make anode-side electrical contacting of the laser diodes 500 possible.

FIG. 4 shows a schematic perspective view of the first surface 101 of the variant of the laser bar chip 100 shown in FIG. 3. The anode contacts 810, 820, 830, 840 are shown to be partially transparent in FIG. 4 in order to also make it possible to represent the waveguide structures 600 of the laser diodes 500 and the anode openings 420 in the passivation 410.

FIG. 4 shows that each of the anode contacts 810, 820, 830, 840 in each case partially covers the waveguide structures 600 of all laser diodes 500. This cannot be seen in FIG. 3. In this case, however, the first anode contact 810 is electrically connected only to the first laser diode 500, 510 and the second laser diode 500, 520. The second anode contact 820 is electrically connected only to the third laser diode 500, 530 and the fourth laser diode 500, 540. The third anode contact 830 is electrically connected only to the fifth laser diode 500, 550. The fourth anode contact 840 is electrically connected only to the sixth laser diode 500, 560. This is achieved by the passivation 410 comprising anode openings 420 in the region between the first laser diode 500, 510 and the first anode contact 810 and in the region between the second laser diode 500, 520 and the first anode contact 810, while the passivation 410 electrically insulates the first laser diode 500, 510 and the second laser diode 500, 520 from the second anode contact 820, the third anode contact 830 and the fourth anode contact 840 and the passivation 410 also electrically insulates the first anode contact 810 from the third laser diode 500, 530, the fourth laser diode 500, 540, the fifth laser diode 500, 550 and the sixth laser diode 500, 560. This applies correspondingly to the further laser diodes 500 and the further anode contacts 810, 820, 830, 840.

The geometry of the anode contacts 810, 820, 830, 840 can also be selected differently than in FIG. 4.

The first laser diode 500, 510 and the sixth laser diode 500, 560 are electrically connected to one another on the cathode side via the epitaxial layer 400 and via a first section 210 of the substrate 200. The second laser diode 500, 520 and the third laser diode 500, 530 are correspondingly electrically connected to one another on the cathode side via the epitaxial layer 400 and via a second section 220 of the substrate 200. The fourth laser diode 500, 540 and the fifth laser diode 500, 550 are also electrically connected to one another on the cathode side via the epitaxial layer 400 and via a third section 230 of the substrate 200.

In contrast, in the region between the first laser diode 500, 510 and the second laser diode 500, 520, the epitaxial layer 400 comprises an electrically non-conductive interruption 440. In addition, the first section 210 of the substrate 200 is electrically insulated from the second section 220 of the substrate 200 by an electrically non-conductive region 240. As a result, the first laser diode 500, 510 and the second laser diode 500, 520 are not electrically connected to one another on the cathode side. Correspondingly, the epitaxial layer 400 also comprises an electrically non-conductive interruption 440 between the third laser diode 500, 530 and the fourth laser diode 500, 540, and the second section 220 of the substrate 200 is electrically insulated from the third section 230 by a further non-conductive region 240, such that the third laser diode 500, 530 and the fourth laser diode 500, 540 are also not electrically connected to one another on the cathode side. Furthermore, in this example of the laser bar chip 100, the fifth laser diode 500, 550 and the sixth laser diode 500, 560 are also not electrically connected to one another on the cathode side.

The first cathode contact 710 is electrically connected to the cathode side of the first laser diode 500, 510 via the first section 210 of the substrate 200 and is also electrically connected to the cathode side of the sixth laser diode 500, 560. The second cathode contact 720 is electrically connected to the cathode side of the second laser diode 500, 520 and to the cathode side of the third laser diode 500, 530 via the second section 220 of the substrate 200. The third cathode contact 730 is electrically connected to the cathode side of the fourth laser diode 500, 540 and to the cathode side of the fifth laser diode 500, 550 via the third section 230 of the substrate 200.

In the variant of the laser bar chip 100 shown in FIG. 3, each of the laser diodes 500 can thereby be individually driven and supplied with electrical voltage and with electrical current. The first laser diode 500, 510 can be driven via the first anode contact 810 and the first cathode contact 710. The second laser diode 500, 520 can be driven via the first anode contact 810 and the second cathode contact 720. The third laser diode 500, 530 can be driven via the second anode contact 820 and the second cathode contact 720. The fourth laser diode 500, 540 can be driven via the second anode contact 820 and the third cathode contact 730. The fifth laser diode 500, 550 can be driven via the third anode contact 830 and the third cathode contact 730. The sixth laser diode 500, 560 can be driven via the fourth anode contact 840 and the first cathode contact 710.

For manufacturing the variant of the laser bar chip 100 shown in FIG. 3, first the substrate 200 comprising the epitaxial layer 400 arranged on the top side 201 is provided in a known manner. Subsequently, the waveguide structures 600 of the laser diodes 500 are formed in the epitaxial layer 400 in a known manner. For example, before the anode contacts 810, 820, 830, 840 are generated, the electrically non-conductive interruptions 440 in the epitaxial layer 400 and the non-conductive regions 240 in the substrate 200 can be applied. This can be effected, for example, by a FIB process (irradiation with a focused ion beam), by which the conductivity of the epitaxial layer 400 and of the substrate 200 is eliminated in a location-dependent manner by destruction of the doping. In this case, the electrically non-conductive interruptions 440 of the epitaxial layer 400 and the non-conductive regions 240 of the substrate 200 can expediently be applied jointly and simultaneously. Subsequently, the anode contacts 810, 820, 830, 840 and the cathode contacts 710, 720, 730 can be applied and structured. A passivation 790 can optionally be arranged between the individual cathode contacts 710, 720, 730, as shown in FIG. 3. Of course, the order of the processing steps described can also be selected differently.

FIG. 5 shows a schematic sectional side view of a further variant of the laser bar chip 100. The variant shown in FIG. 5 largely corresponds to the variant shown in FIG. 3 and can be manufactured according to the method described above. However, in the variant shown in FIG. 5, after the cathode contacts 710, 720, 730 have been applied, a rewiring structure 900 is also formed on the second surface 102 of the laser bar chip 100. The rewiring structure 900 comprises one or more layers of electrically non-conductive and electrically conductive materials and makes it possible to reconfigure the geometry at the cathode contact 710, 720, 730 on the second surface 102 of the laser bar chip 100 without in this case generating unwanted short circuits between the individual cathode contacts 710, 720, 730. The rewiring structure 900 can also be used to selectively connect individual cathode contacts 710, 720, 730 to one another in an electrically conductive manner.

In a further variant of the laser bar chip 100, alternatively or additionally, a rewiring structure can be formed on the first surface 101 of the laser bar chip 100. This rewiring structure can in turn comprise layers of electrically non-conductive and conductive materials. This rewiring structure can be provided to reconfigure the geometry of the anode contacts 810, 820, 830, 840, 850, 860 accessible on the first surface 101 of the laser bar chip 100 or to connect individual or all of the anode contacts 810, 820, 830, 840, 850, 860 to one another in an electrically conductive manner.

FIG. 6 shows a schematic sectional side view of a further variant of the laser bar chip 100. In this and all of the variants of the laser bar chip 100 described below, the first laser diode 500, 510, the second laser diode 500, 520, the third laser diode 500, 530, the fourth laser diode 500, 540, the fifth laser diode 500, 550 and the sixth laser diode 500, 560 are arranged next to one another in this order. This variant of the laser bar chip 100 comprises, in addition to the first cathode contact 710, the second cathode contact 720 and the third cathode contact 730, a fourth cathode contact 740, a fifth cathode contact 750 and a sixth cathode contact 760. The cathode contacts 710, 720, 730, 740, 750, 760 are in turn arranged on the second surface 102 of the laser bar chip 100. In addition, this variant of the laser bar chip 100 comprises, in addition to the first anode contact 810, the second anode contact 820, the third anode contact 830 and the fourth anode contact 840, a fifth anode contact 850 and a sixth anode contact 860. The anode contacts 810, 820, 830, 840, 850, 860 are in turn arranged on the first surface 101 of the laser bar chip 100.

In the variant of the laser bar chip 100 shown in FIG. 6, the substrate 200 is electrically non-conductive. In this case, the substrate 200 can comprise, for example, an undoped semi-conductor material. A first through-contact 310, a second through-contact 320, a third through-contact 330, a fourth through-contact 340, a fifth through-contact 350 and a sixth through-contact 360 are formed in the substrate 200. The first cathode contact 710 is electrically connected to the cathode side of the first laser diode 500, 510 via the first through-contact 310. The second cathode contact 720 is electrically connected to the cathode side of the second laser diode 500, 520 via the second through-contact 320. The third cathode contact 730 is electrically connected to the cathode side of the third laser diode 500, 530 via the third through-contact 330. The fourth cathode contact 740 is electrically connected to the cathode side of the fourth laser diode 500, 540 via the fourth through-contact 340. The fifth cathode contact 750 is electrically connected to the cathode side of the fifth laser diode 500, 550 via the fifth through-contact 350. The sixth cathode contact 760 is electrically connected to the cathode side of the sixth laser diode 500, 560 via the sixth through-contact 360. Thus, in the variant of the laser bar chip 100 shown in FIG. 6, each laser diode 500 is electrically connected to precisely one of the cathode contacts 710, 720, 730, 740, 750, 760.

The first anode contact 810 is electrically connected to the anode side of the first laser diode 500, 510 via one of the anode openings 420 in the passivation 410. By contrast, the first anode contact 810 is electrically insulated from the remaining laser diodes 500. The second anode contact 820 is electrically connected to the anode side of the second laser diode 500, 520. The third anode contact 830 is electrically connected to the anode side of the third laser diode 500, 530. Correspondingly, the further anode contacts 840, 850, 860 are also each connected to precisely one of the laser diodes 500, 540, 550, 560. Thus, each of the laser diodes 500 of the variant of the laser bar chip 100 shown in FIG. 6 has both an individual cathode contact 710, 720, 730, 740, 750, 760 and an individual anode contact 810, 820, 830, 840, 850, 860.

In the variant of the laser bar chip 100 shown in FIG. 6, the epitaxial layer 400 comprises electrically conductive interruptions 440 between the first laser diode 500, 510 and the second laser diode 500, 520, between the second laser diode 500, 520 and the third laser diode 500, 530, between the third laser diode 500, 530 and the fourth laser diode 500, 540, between the fourth laser diode 500, 540 and the fifth laser diode 500, 550 and between the fifth laser diode 500, 550 and the sixth laser diode 500, 560. Thus, the cathode sides of all laser diodes 500 are electrically insulated from one another. In this variant of the laser bar chip 100, the electrically non-conductive interruptions 440 are formed as trenches 450 in the epitaxial layer 400.

For manufacturing the variant of the laser bar chip 100 shown in FIG. 6, first the electrically non-conductive substrate 200 comprising the epitaxial layer 400 arranged on the top side 201 is provided in a known manner. Subsequently, the laser diodes 500 are formed in the epitaxial layer 400 in a known manner. Then, the anode contacts 810, 820, 830, 840, 850, 860 can be formed in a known manner on the first surface 101 of the laser bar chip 100 and electrically connected to the anode sides of the laser diodes 500. Subsequently, the electrically non-conductive interruptions 440 can be applied in the epitaxial layer 400, for example by etching the trenches 450. The trenches 450 can subsequently optionally also be filled with an electrically non-conductive material. Alternatively, however, it would also be possible to apply the electrically non-conductive interruptions 440 in turn by an FIB method. Before or after this, the through-contacts 310, 320, 330, 340, 350, 360 can be applied, for example by first etching openings proceeding from the second surface 102 into the substrate 200 and subsequently filling these openings with an electrically conductive material, for example gold or copper, for example by a vapor deposition method. Then, the cathode contacts 710, 720, 730, 740, 750, 760 are formed on the second surface 102 of the laser bar chip 100 and electrically connected to the cathode sides of the laser diodes 500.

FIG. 7 shows a schematic sectional side view of a further variant of the laser bar chip 100. The variant shown in FIG. 7 largely corresponds to the variant of the laser bar chip 100 shown in FIG. 6. In the manufacture of the variant shown in FIG. 7, however, a rewiring structure 900 was also formed on the second surface 102 of the laser bar chip 100 subsequent to the manufacturing method described above. The rewiring structure 900 can in turn comprise layers of non-conductive and conductive materials and serve to reconfigure the geometry of the cathode contacts 710, 720, 730, 740, 750, 760 accessible on the second surface 102 or to electrically connect individual or all of the cathode contacts 710, 720, 730, 740, 750, 760 to one another.

In a further variant of the laser bar chip 100, alternatively or additionally, a rewiring structure can be formed on the first surface 101 of the laser bar chip 100. This rewiring structure can in turn comprise layers of electrically non-conductive and conductive materials. This rewiring structure can be provided to reconfigure the geometry of the anode contacts 810, 820, 830, 840, 850, 860 accessible on the first surface 101 of the laser bar chip 100 or to electrically connect individual or all of the anode contacts 810, 820, 830, 840, 850, 860 to one another.

FIG. 8 shows a schematic sectional side view of a further variant of the laser bar chip 100. The variant shown in FIG. 8 largely corresponds to the variant of FIG. 6.

However, the variant of the laser bar chip 100 shown in FIG. 8 has only the first anode contact 810. This is electrically connected to the anode sides of all six laser diodes 500, 510, 520, 530, 540, 550, 560. However, as in the variant of FIG. 6, the cathode sides of the laser diodes 500 are connected to a respective individual cathode contact 710, 720, 730, 740, 750, 760. Thus, in the variant of the laser bar chip 100 shown in FIG. 8, each laser diode 500 can also be individually driven.

The manufacture of the variant of the laser bar chip 100 shown in FIG. 8 is effected like the manufacture of the variant shown in FIG. 6. However, the electrically non-conductive interruptions 440 in the epitaxial layer 400 are already formed before the first anode contact 810 is applied, for example by etching trenches 450. These are subsequently filled with an electrically non-conductive material 455. The first anode contact 810 is then formed on the first surface 101 of the laser bar chip 100.

In further variants of the laser bar chip 100 not shown in the figures, the latter is formed as in the variants of FIGS. 6 and 8, but has more than one and less than six anode contacts 810, 820, 830, 840, 850, 860. In this case, each of the anode contacts 810, 820, 830, 840, 850, 860 can be electrically connected to one or more of the laser diodes 500. In these variants, too, the rewiring structures 900 on the first surface 101 and/or on the second surface 102 of the laser bar chip 100 are possible. A rewiring structure 900 on the second surface 102 is also possible in the variant shown in FIG. 8.

FIG. 9 shows a schematic sectional side view of a further variant of the laser bar chip 100. The variant shown in FIG. 9 has only the first cathode contact 710, the second cathode contact 720, the third cathode contact 730 and the fourth cathode contact 740. In addition, this variant has only the first anode contact 810, the second anode contact 820 and the third anode contact 830.

In this variant, the first anode contact 810 is electrically connected to the anode sides of the first laser diode 500, 510 and the second laser diode 500, 520. The second anode contact 820 is electrically connected to the anode sides of the third laser diode 500, 530 and the fourth laser diode 500, 540. The third anode contact 830 is electrically connected to the anode sides of the fifth laser diode 500, 550 and the sixth laser diode 500, 560.

The first cathode contact 710 is electrically connected to the cathode side of the first laser diode 500, 510. The second cathode contact 720 is electrically connected to the cathode sides of the second laser diode 500, 520 and the third laser diode 500, 530. The third cathode contact 730 is electrically connected to the cathode sides of the fourth laser diode 500, 540 and the fifth laser diode 500, 550. The fourth cathode contact 740 is electrically connected to the cathode side of the sixth laser diode 500, 560.

In the variant of the laser bar chip 100 shown in FIG. 9, the substrate 200 is in turn non-conductive, for example as an undoped semiconductor substrate. The epitaxial layer 400 in turn comprises an electrically non-conductive interruption 440 between the first laser diode 500, 510 and the second laser diode 500, 520, by which the cathode sides of the first laser diode 500, 510 and the second laser diode 500, 520 are electrically insulated from one another. Correspondingly, the epitaxial layer 400 also comprises non-conductive interruptions 440 between the third laser diode 500, 530 and the fourth laser diode 500, 540 and between the fifth laser diode 500, 550 and the sixth laser diode 500, 560. The non-conductive interruptions 440 can in turn be formed as trenches 450 which are filled with an electrically non-conductive material 455. It is expedient if the electrically non-conductive interruptions 440 are generated during the manufacture of the variant of the laser bar chip 100 shown in FIG. 9 before the anode contacts 810, 820, 830 are applied.

In the variant of the laser bar chip 100 shown in FIG. 9, the anode contacts 810, 820, 830 are in turn arranged on the first surface 101 of the laser bar chip 100. In addition, in this variant, the cathode contacts 710, 720, 730, 740 are also arranged on the first surface 101 of the laser bar chip 100. For this purpose, the passivation 410 arranged on the epitaxial layer 400 and the waveguide structures 600 comprises cathode openings 430 which make an electrically conductive connection possible between the cathode contacts 710, 720, 730, 740 and the sections of the epitaxial layer 400 connected to the cathode sides of the respective laser diodes 500.

For manufacturing the variant of the laser bar chip 100 shown in FIG. 9, first the non-conductive substrate 200 comprising the epitaxial layer 400 arranged on the top side 201 is provided in a known manner. Subsequently, the laser diodes 500 comprising their waveguide structures 600 are manufactured in the epitaxial layer 400 in a known manner. Even before a mask used for manufacturing the waveguide structures 600 is removed, it can be used for applying the trenches 450 and the cathode openings 430. After filling the trenches 450 forming the electrically non-conductive interruptions 440 with the electrically non-conductive material 455, the cathode contacts 710, 720, 730, 740 and the anode contacts 810, 820, 830 can be formed on the first surface 101 of the laser bar chip 100.

FIG. 10 shows a schematic sectional side view of a further variant of the laser bar chip 100. The variant shown in FIG. 10 largely corresponds to the variant of the laser bar chip 100 shown in FIG. 9. However, after the cathode contacts 710, 720, 730, 740 and the anode contacts 810, 820, 830 have been applied, a rewiring structure 900 has also been created on the first surface 101 of the laser bar chip 100. The rewiring structure 900 can comprise layers of electrically non-conductive and electrically conductive materials and can serve to modify the geometry of the cathode contacts 710, 720, 730, 740 and the anode contacts 810, 820, 830 accessible on the first surface 101 of the laser bar chip 100. The rewiring structure 900 can also serve to electrically connect individual or all of the cathode contacts 710, 720, 730, 740 or the anode contacts 810, 820, 830 to one another.

Like all further variants of the laser bar chip 100, the variants of the laser bar chip 100 shown in FIGS. 9 and 10 can be designed with a number of laser diodes 500 other than that shown. The number of cathode contacts 710, 720, 730, 740, 750, 760 and the anode contacts 810, 820, 830, 840, 850, 860 can also be selected differently than shown in each case.

The invention has been illustrated and described in more detail on the basis of the preferred example embodiments. Nevertheless, the invention is not restricted to the disclosed examples. Other variations can be derived by a person skilled in the art.

### List of Reference Numerals

100 laser bar chip
101 first surface
102 second surface
110 length
120 width
200 substrate
201 top
210 first portion
220 second portion
230 third portion
240 non-conductive region
310 first via contact
320 second via contact
330 third via contact
340 fourth via contact
350 fifth via contact
360 sixth via contact
400 epitaxial layer
410 passivation
420 anode opening
430 cathode opening
440 electrically non-conductive interruption
450 trench
455 electrically non-conductive material
500 laser diode
510 first laser diode
520 second laser diode
530 third laser diode
540 fourth laser diode
550 fifth laser diode
560 sixth laser diode
570 seventh laser diode
580 eighth laser diode
600 waveguide structure
610 outcoupling facet
620 active layer
710 first cathode contact
720 second cathode contact
730 third cathode contact
740 fourth cathode contact
750 fifth cathode contact
760 sixth cathode contact
790 passivation
810 first anode contact
820 second anode contact
830 third anode contact
840 fourth anode contact
850 fifth anode contact
860 sixth anode contact
900 rewiring structure

1. A laser bar chip
wherein the laser bar chip comprises at least a first laser diode and a second laser diode and a third laser diode,
wherein the first laser diode, the second laser diode, and the third laser diode each comprise a waveguide structure,
wherein the laser bar chip comprises a first cathode contact which is electrically connected to the first laser diode,
and a second cathode contact which is electrically connected to the second laser diode and the third laser diode, and
the laser bar chip comprises a first anode contact which is electrically connected to the first laser diode and to the second laser diode.

2. (canceled)

3. The laser bar chip according to claim 2,
further comprising a second anode contact which is electrically connected to the third laser diode.

4. The laser bar chip according to claim 3,
further comprising an electrically non-conductive passivation arranged on the waveguide structure of the first laser diode,
wherein the passivation is opened in the region of the first anode contact, so that the first anode contact is electrically connected to the first laser diode,
wherein the second anode contact is electrically insulated from the first laser diode by the passivation.

5. The laser bar chip according to claim 1,
wherein the first anode contact is arranged on a first surface of the laser bar chip,
wherein the first cathode contact and the second cathode contact are arranged on a second surface of the laser bar chip.

6. The laser bar chip according to claim 5,
further comprising a rewiring structure formed on the second surface of the laser bar chip.

7. The laser bar chip according to claim 1,
wherein the first anode contact, the first cathode contact and the second cathode contact are arranged together on a first surface of the laser bar chip.

8. The laser bar chip according to claim 5,
further comprising a rewiring structure is formed on the first surface of the laser bar chip.

9. The laser bar chip according to claim 1,
wherein an epitaxial layer of the laser bar chip comprises an electrically non-conductive interruption between the first laser diode and the second laser diode.

10. The laser bar chip according to claim 9,
wherein the epitaxial layer is arranged on an electrically conductive substrate,
wherein a first section of the substrate and a second section of the substrate are electrically insulated from one another by an electrically non-conductive region,
wherein the first cathode contact is electrically connected to the first laser diode via the first section of the substrate and the second cathode contact is electrically connected to the second laser diode via the second section of the substrate.

11. The laser bar chip according to claim 9,
wherein the epitaxial layer is arranged on an electrically non-conductive substrate,
wherein the substrate comprises an electrically conductive first through-contact and an electrically conductive second through-contact,
wherein the first cathode contact is electrically connected to the first laser diode via the first through-contact and the second cathode contact is electrically connected to the second laser diode via the second through-contact.

12. A method of manufacturing a laser bar chip
comprising:
providing a substrate comprising an epitaxial layer arranged on a top side;
forming at least a first laser diode, a second laser diode and a third laser diode in the epitaxial layer, wherein the first laser diode, the second laser diode and the third laser diode each comprise a waveguide structure;
forming a first cathode contact which is electrically connected to the first laser diode,
and a second cathode contact which is electrically connected to the second laser diode and the third laser diode, and
forming a first anode contact which is electrically connected to the first laser diode and to the second laser diode.

13. The method according to claim 12,
wherein the method further comprises:
generating an electrically non-conductive interruption in the epitaxial layer between the first laser diode and the second laser diode.

14. The method according to claim 13,
wherein the substrate is electrically non-conductive,
wherein the method further comprises:
applying an electrically conductive first through-contact and an electrically conductive second through-contact in the substrate;
wherein the first cathode contact is electrically connected to the first laser diode via the first through-contact and the second cathode contact is electrically connected to the second laser diode via the second through-contact.

15. The method according to claim 13,
wherein the substrate is electrically conductive,
wherein the method further comprises:
applying an electrically non-conductive region in the substrate in order to electrically insulate a first section of the substrate and a second section of the substrate from one another;
wherein the first cathode contact is electrically connected to the first laser diode via the first section of the substrate and the second cathode contact is electrically connected to the second laser diode via the second section of the substrate.

16. The method according to claim 15,
wherein the electrically non-conductive interruption in the epitaxial layer and the electrically non-conductive region in the substrate are generated jointly by a FIB process.

17. The method according to claim 13,
wherein the electrically non-conductive interruption is generated by etching a trench in the epitaxial layer.

18. The method according to claim 17,
wherein the trench is filled with an electrically non-conductive material.
